(19) United States
(12) Patent Application Publication
(10) Pub. No.: US 2002/0153913 A1
(43) Pub. Date: Oct. 24, 2002

(54) Probe for the probe card

(75) Inventors: Masao Okubo, Amagasaki-shi (JP); Kazumasa Okubo, Amagasaki-shi (JP); Yoshiaki Tani, Amagasaki-shi (JP); Yasuo Miura, Amagasaki-shi (JP); Toshihumi Han, Amagasaki-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Japan Electronic Materials Corp., Amagasaki-shi (JP)

(21) Appl. No.: 09/993,675

(22) Filed: Nov. 27, 2001

(30) Foreign Application Priority Data
Nov. 28, 2000 (JP) 2000-361062

(51) Int. Cl. G01R 31/02

(52) U.S. Cl. 324/761

(57) ABSTRACT

To enable a probe to be applied to a probe card for use in inspecting the IC chip having a fine pitch such as 100 μm, for example, as a pitch size between the electrodes by improving the probe for the probe card having a bare wire structure made of palladium alloy and the probe for the probe card having a bare wire structure made of beryllium copper alloy. There is provided a probe for the probe card characterized in that the same is comprised of a structure where either nickel plating or nickel alloy plating is applied to the surface of the core material made of either palladium alloy or beryllium copper alloy. In addition, there is provided a probe for the probe card having a structure where either nickel plating or nickel alloy plating is applied to the surface of the core material made of either palladium alloy or beryllium copper alloy and further the wire drawing with the wire drawing dies is applied to it.

### DETAILED DESCRIPTION OF THE INVENTION

1. Technical Field of Invention

This invention relates to a probe for a probe card that is used in a probe card for inspecting an electrical characteristic of an IC chip.

2. Description of Related Art

In the case that an electrical characteristic of an IC chip forming a semiconductor device is to be inspected, a device called as a probe card is used. FIG. 1 is a sectional view for showing a configuration of the vertical type probe card. As shown in this figure, the vertical probe card is constituted by a plurality of probes 1 for probe card (hereinafter merely called as a “probe”) which have curved portions 1a and forming a needle-like shape; a guide 2 for use in suspending these probes 1 and fixing them; and a base plate 3 where each of wiring patterns having rear ends of the probes connected by soldering for every probes 1 is formed. The probe 1 is connected to a terminal arranged at a circumference of the base plate 3 through the wiring pattern. When an IC chip is to be inspected, an inspection device called as a prober is connected to the terminal of the base plate 3. The guide 2 is constituted by an upper guide plate 21 having guide holes 21a where each of the plurality of probes 1 passes through the holes; a lower guide plate 22 arranged in parallel with the upper guide plate 21 while being spaced apart by a predetermined distance below it and having guide holes 22a where each of a plurality of probes 1 passes through the holes; a probe fixing member 23 arranged over the upper guide plate 21 for fixing a plurality of probes 1; and a supporting member 24 suspended down from the rear surface of the base plate 3 so as to support the upper guide plate 21 and the lower guide plate 22.

Reference numeral 4 denotes a wafer mounting table, and a wafer 5 formed with a plurality of IC chips 51 to be inspected is mounted on this wafer table 4. Reference symbol 51a denotes an electrode formed at the surface of the IC chip 51. A vertical type probe card is made such that the tip of the probe 1 is contacted vertically to the electrode 51a of the IC chip 51 and the tip of the probe 1 is positioned just above the electrode 51a. Then, the wafer mounting table 4 is lifted up toward the probe 1 to cause the electrode 51a of the IC chip 51 to be contacted with the tip of the probe 1.

In this case, an aluminum-copper alloy film containing aluminum and copper, or an aluminum film forms the electrode 51a of the IC chip 51. As the surface of the electrode 51a, an oxidization film composed of thin aluminum oxide is formed. Since this oxidization film is an insulator, mere contact of the tip of the probe 1 with the surface of the electrode 51a does not enable the tip of the probe 1 to be contacted with the aluminum-copper alloy film positioned below the oxide film, resulting in that an electrical connection between the tip of the probe 1 and the aluminum-copper alloy film can not be attained.

Due to this fact, after the tip of the probe 1 is contacted with the electrode 51a, the wafer mounting table 4 is lifted up. An operation in which the tip of the probe 1 is contacted with the electrode 51a and then the IC chip 51 is lifted up toward the probe 1 is called as an over-drive. A distance where the IC chip 51 is lifted up after contact with the probe 1 is called as an amount of over-drive. In general, this amount of over-drive is about 50 to 100 μm. As shown in FIG. 2, in the vertical type probe card, the probe 1 having a curved portion la is used. Then, when an over-drive is applied after the tip of the probe 1 is contacted with the electrode 51a, the probe 1 is operated such that as shown in FIG. 3 its curved portion la is resiliently deformed and flexed to cause the probe tip to press against the electrode 51a with a predetermined contact force (a probe force). With such an operation as above, the oxide film is broken and removed from the surface of the electrode 51a at the contact point between the probe 1 and the electrode 51a, resulting in that the tip of the probe 1 and the aluminum-copper alloy film of the electrode 51a can be directly contacted. Further, a contact force (g) is increased in proportion to a value of the amount of over-drive (μm).

FIG. 4 is an illustrative view for showing an outer appearance shape of the probe used in the vertical type probe card. A size of the probe will be described as follows, wherein a diameter (an outer diameter) D is 80 μm, a tip length L1 is 450 μm, the most-tip diameter (d) is about 25 to 30 μm, and a length of the curved part L2 is about 2 mm. The probe with the diameter D of 80 μm is used for the vertical type probe card for use in inspecting the IC chip having a pitch size between the electrodes of 200 μm. The prior art probe has a non-plated bare wire structure showing a circular sectional surface and this probe is made from tungsten, beryllium copper alloy or palladium alloy. These metallic materials are superior as electrical contact point materials. As beryllium copper alloy, an alloy of Cu—Be by 2 mass % containing beryllium by 2 mass % can be applied. In addition, as palladium alloy, either Paliney 7 (a product name) or Paliney 6 (a product name) developed by NEY Corporation in U.S.A can be applied, and Paliney 7 is used most frequently. Paliney 7 (corresponding to ASTM American Society for Testing and Materials B-540) is 6-element alloy containing palladium as its major element. Chemical components of Paliney 7 are as follows: Pd: 35 mass %, Ag: 30 mass %, Pt: 10 mass %, Au: 10 mass %, Cu: 14 mass % and Zn: 1 mass %. Paliney 6 (corresponding to ASTM American Society for Testing and Materials B-563) is a 4-element alloy containing palladium as its major element. Chemical components of Paliney 6 are as follows: Pd: 42 to 44 mass %, Ag: 38 to 41 mass %, Pt: 0 to 1 mass %, Cu: 16 to 17 mass %.

The probe made of tungsten is manufactured such that tungsten powder is formed with a press to attain a molded product, a repeated application of electrical heating, hot processing and a heat treatment for this molded product causes this molded product to become a wire material of predetermined diameter, then the wire material is drawn by wire drawing dies to attain a fine wire for the probe, and both a polishing work for forming a tip shape and a bending work for forming a curved portion are applied to the fine wire for the probe cut to a predetermined length. Further, the probe made of either beryllium copper alloy or palladium alloy is manufactured such that raw material metals are mixed to each other, melted in vacuum condition to make billets, a repeated application of both a cold processing and a heat treatment is set against the billets to attain a wire material having a predetermined diameter, then the wire material is drawn by wire drawing dies to attain a fine wire for the probe, and both a polishing work for forming a tip shape and a bending work for forming a curved portion are applied to the fine wire for the probe cut to a predetermined length. The probe used in the vertical type probe card is connected at its rear end to the base plate by soldering. Due to this fact, the probe made of tungsten is applied with nickel plating only at the rear end portion.

As described above, the prior art probe used for the vertical type probe card was made of tungsten, beryllium copper alloy or palladium alloy and had non-plated bare wire structure.

### SUMMARY OF INVENTION

Irrespective of the foregoing fact, a pitch size between the electrodes of the IC chip is gradually decreased as a fine size of the semiconductor integrated circuit is promoted and correspondingly the probe diameter D is also gradually made fine. Then, in the case that the IC chip having its pitch size between the electrodes of 100 μm, it becomes necessary to use the probe with its diameter D being 65 μm.

However, in the case of palladium alloy probe with a diameter D being 65 μm in the prior art probe having a bare wire structure used for the vertical type probe card, a predetermined contact force can not be attained when an over-drive is applied, so that no electrical connection can be made between the tip of the probe and the aluminum-copper alloy film at the electrode of the IC chip. Due to this fact, there was a problem that it is not possible to perform an inspection test for the IC chip with a pitch size between the electrodes being 100 μm. In addition, also in the case of probe made of beryllium copper alloy with a diameter D being 65 μm, a predetermined contact force can not be attained when the over-drive is applied.

To the contrary, the tungsten probe with a diameter D being 65 μm can attain a predetermined contact force when the over drive is applied because tungsten is superior in view of its spring characteristic as metallic material as compared with that of palladium alloy and beryllium copper alloy. However, the tungsten probe of bare wire structure has a problem to be described as follows. The tip of the tungsten probe becomes to show a high temperature and easily becomes oxidized because the inspection temperature for the IC chip is 85° C. or 150° C. As the surface of the tip of the tungsten probe is oxidized, a part of aluminum oxide removed from the surface of the electrode of the IC chip due to the over drive is easily adhered to the tip of the probe. In this way, when aluminum oxide of insulating material adheres to the tip of the tungsten probe, a contact resistance between the probe tip and the electrode is increased. Due to this fact, when such a probe as above is continued to be used, the electrical connection becomes finally poor, resulting in that an inspection test for the IC chip can not be carried out accurately.

In addition, in the case of the palladium alloy probe and the beryllium copper alloy probe, there occurs no possibility that a poor electrical connection is produced by adhesion of aluminum oxide because the surface is hardly oxidized even at an inspection test temperature for the IC chip.

It is an object of the present invention to provide a probe for a probe card which can be applied to the probe card for performing an inspection of the IC chip having a fine pitch such as 100 μm, for example, as an inter-electrode pitch size and which can be adapted for a reduced small inter-electrode pitch size of the IC chip due to a development of fine formation of the semiconductor integrated circuit by improving a probe for a probe card having a bare wire structure made of palladium alloy and a probe for a probe card having a bare wire structure made of beryllium copper alloy.

In order to accomplish the aforesaid object, the invention described in claim 1 provides a probe for a probe card characterized in that the same has a structure in which either a nickel plating or a nickel alloy plating is applied to the surface of a core member made of palladium alloy or beryllium copper alloy.

The invention described in claim 2 consists in a probe for a probe card characterized in that the same has a structure in which either a nickel plating or a nickel alloy plating is applied to the surface of the core member comprised of either palladium alloy or beryllium copper alloy and a wire drawing work with the wire drawing dies is applied to the wire.

The invention described in claim 3 provides a probe for the probe card according to claim 1 characterized in that a gold plating is further applied to the upper-most surface. The invention described in claim 4 consists in the probe for the probe card according to claim 2 characterized in that a gold plating is further applied to the upper-most surface after the wire drawing operation is performed for the wire.

It is known that nickel and nickel alloy are superior in spring characteristics (such as Young's modulus, and elastic limit) and hardness as compared with those of palladium alloy and beryllium copper alloy. In accordance with the probe of the invention described in claim 1, it is possible to increase a contact force (a probe force) generated under an elastic deformation and flexing of the probe curved portion when the over drive is applied as compared with that of the probe made of palladium alloy or beryllium copper alloy having the prior art bare wire structure because either the nickel plating or the nickel alloy plating is applied to the surface of the core material made of palladium alloy or beryllium copper alloy. With such an arrangement as above, the probe diameter can be made fine to have a size of 65 μm and the inspection test for the IC chip with an inter-electrode pitch size being 100 μm can be carried out. In addition, in accordance with the probe of the invention described in claim 1, it is possible to perform a bending operation having a superior processing accuracy because no spring-back is produced when the curved portion is formed. Further, when the over drive is finished, it is superior in a shape recovering characteristic (a shape recovering force) at the curved portion where the curved portion kept in its flexed state up to now is apt to return to its original shape. Due to this fact, even if the probe is continued to be used repeatedly for a long period of time, the position of the probe tip is not changed, but kept constant, and so its positional displacement in respect to the IC chip electrode is not produced. In the case of the probe in accordance with the invention described in claim 1, if its diameter is 65 μm, it is suitable that a thickness of the nickel plating or nickel alloy plating is 3 μm or more. A reason for this fact consists in that if the thickness is lower than 3 μm, a desired contact force can not be attained. Further, in view of its cost, it is suitable that its upper limit value is 15 μm.

To the contrary, the probe in accordance with the invention described in claim 2 is added with the structure of the probe in accordance with the invention described in claim 1 and processed with a wire drawing operation performed with the wire drawing dies. The plated fine wire for the probe processed with the wire drawing operation under application of the wire drawing dies and finished to a product diameter after being applied with plating is more superior in view of its spring characteristic and hardness as compared with the plated fine wire for probe having the same product diameter where no wire drawing operation is applied because the aforesaid wire drawing operation is applied.

Thus, in accordance with the probe of the invention described in claim 2, it can take a high contact force (a probe force) as compared with that of the prior art probe having bare wire structure made of palladium alloy or beryllium copper alloy and as compared with that of the probe of the invention described in claim 1 when the over drive is applied because the probe has a structure in which either the nickel plating or the nickel alloy plating is applied to the surface of the core member made of palladium alloy or beryllium copper alloy and because the wire drawing operation is performed with the wire drawing dies. With such an arrangement as above, the probe diameter can be set to a fine size of 65 μm and the IC chip with an inter-electrode pitch size being 100 μm can be inspected. In addition, in accordance with the probe of the invention described in claim 2, a superior bending operation showing a high processing accuracy can be carried out when the curved portion is formed more than that of the probe of the invention described in claim 1 and at the same time this is superior in a shape recovering characteristic (a shape recovering force) of the curved portion. In accordance with a result of observation performed through a microscope, the plated surface of the probe in accordance with the invention described in claim 2 has a quite low irregularity as compared with that of the plated surface of the probe in accordance with the invention described in claim 1 and made smooth because the wire drawing operation with the wire drawing dies is carried out. In the case of the probe in accordance with the invention described in claim 2, if its diameter is 65 μm, it is suitable that a thickness of the nickel plating or the nickel alloy plating is 2 μm or more. A reason why this value is suitable consists in the fact that if the value is lower than 2 μm, a desired contact force can not be attained.

In the case of the probe made in accordance with the present invention, as its nickel alloy plating, it is possible to apply a nickel-cobalt alloy plating (Ni/Co alloy plating), a nickel-iron alloy plating (Ni/Fe alloy plating), a nickel-chromium alloy plating (Ni/Cr alloy plating), a nickel-palladium alloy plating (Ni/Pd alloy plating) and a nickel-tellurium-chromium alloy plating (Ni/Te/Cr alloy plating). Then, it is suitable that an amount of inclusion of nickel in the nickel alloy plating is 20 mass % or more. A reason why this value is applied consists in the fact that if the value is lower than 20 mass %, the work hardening at the wire drawing operation is promoted to cause the wire drawing limit to be reduced and the wire drawing characteristic is damaged.

In the case of the probe in accordance with the inventions described in claims 1 and 2, it is also applicable that a gold plating is applied to the uppermost surface of it. When a high frequency signal is flowed in the probe, the probe having the gold plating applied at its uppermost surface can avoid an electrical resistance due to its surface effect. In addition, the gold plating is applied after both a polishing work for forming the tip shape and a bending work for forming the curved portion are carried out. It is suitable that a thickness of the gold plating is about 0.2 to 1.0 μm.

### BRIEF DESCRIPTION OF THE DRAWINGS

FIG. 1 is a sectional view for showing a configuration of a vertical type probe card.

FIG. 2 is a view for illustrating a probe having a curved part used in a vertical type probe card.

FIG. 3 is a view for illustrating a probe having a curved part used in a vertical type probe card.

FIG. 4 is an illustrative view for showing an outer appearance shape of a probe used in a vertical type probe card.

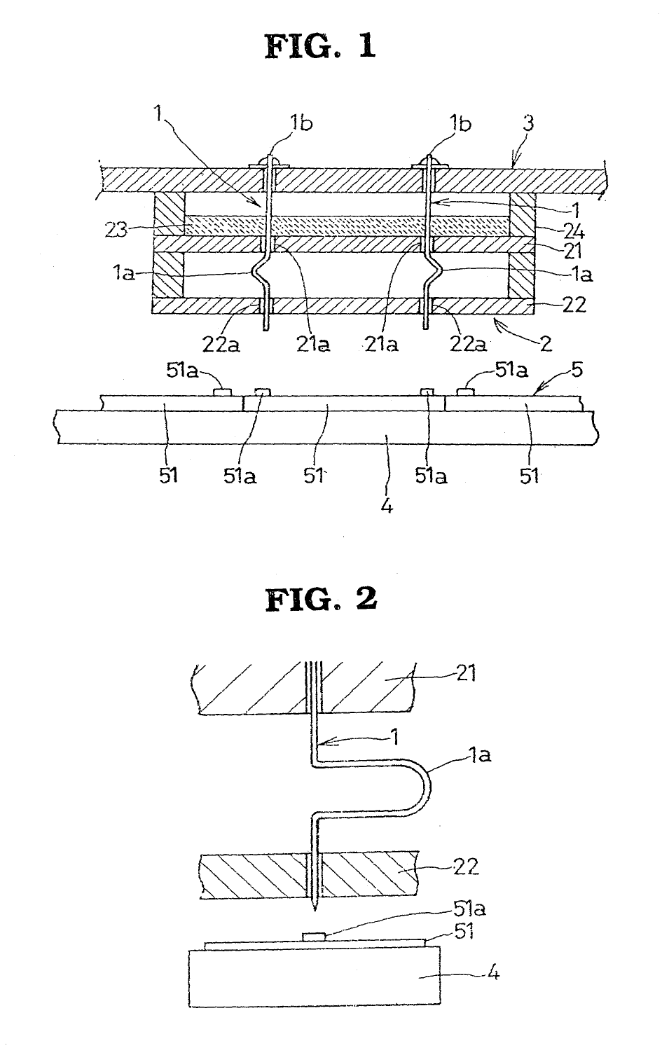

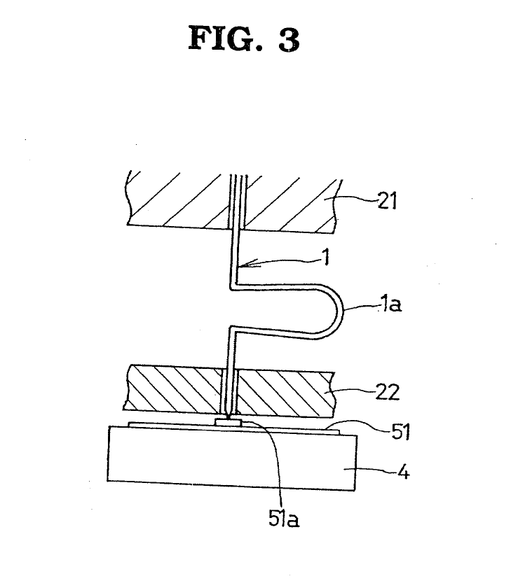

### DETAILED DESCRIPTION

Some embodiments of the present invention will be described as follows. At first, the embodiment relating to the invention described in claim 2 will be described. [Embodiment 1]

The inventors have manufactured a probe with a diameter of 65 μm having a structure in which a nickel plating with a thickness of 5 μm is applied to the surface of the core member made of Paliney 7 of palladium alloy with a circular sectional surface and in which a wire drawing operation is carried out with the wire drawing dies.

A method for manufacturing the probe in accordance with the embodiment 1 will be described. At first, a nickel plated fine wire for the probe with a diameter of 118 μm and a plating thickness of 9 μm has been manufactured starting from the wire material with a diameter of 100 μm made of Paliney 7 having the aforesaid chemical composition through the following steps. That is, these steps are (1) an electrolysis degreasing step, (2) a water washing step, (3) an activating step, (4) a water washing step, (5) a strike plating step, (6) a water washing step, (7) a plating step, (8) a water washing step, (9) a drying step and (10) a take-up step. In the plating step for performing an electrical plating, a plating bath called as “Watts bath” composed of nickel sulfate (NiSO₄.6H₂O), nickel chloride (NiCl₂.6H₂O) and boric acid (H₃BO₃) was used for the wire material made of Paliney 7 with a diameter of 100 μm, and a nickel plating with a nickel thickness of 9 μm was applied with a cathode current density being 2 to 10A/dm².

Then, this nickel plated fine wire for the probe was made fine in sequence with a plurality of wire drawing dies to attain the nickel plated fine wire for the probe applied with the wire drawing operation and having a diameter of 65 μm and a plated thickness of 5 μm. A wire drawing machine is classified as a slip type continuous wire drawing machine. In this case, a cone-type wet continuous wire drawing machine for a fine wire was used. As the wire drawing dies, natural diamond dies were used. A rate of reduction of sectional surface was set to about 10 to 20% for one wire drawing dies.

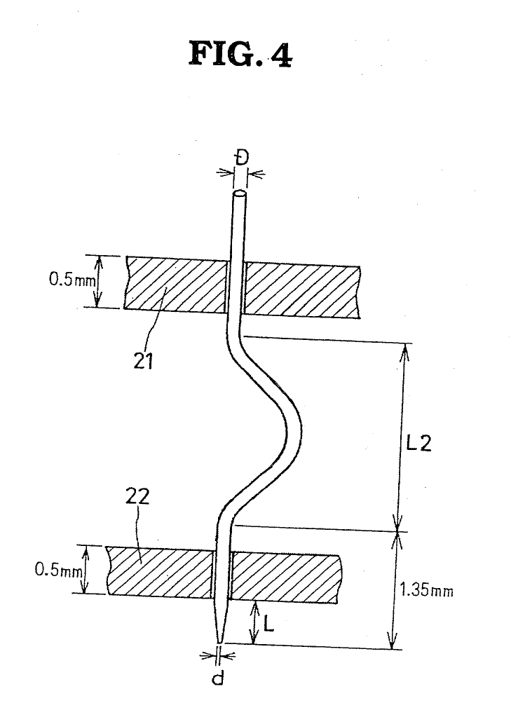

Then, the nickel plated fine wire for the probe applied with the wire drawing operation described above is cut under a predetermined length pitch, a pitch of length of 60 mm, for example. Both a polishing operation for forming a tip shape and a bending operation for forming a curved portion were carried out for the nickel plated fine wire of a predetermined length for the probe applied with the wire drawing operation to attain the probe with a diameter of 65 μm having a structure in which a nickel plating of a thickness of 5 μm was applied at the surface of the core material made of Paliney 7 and a wire drawing operation with some wire drawing dies were performed. A size of this probe (refer to FIG. 4) has a diameter (an outer diameter) D of 65 μm, a tip length L1 of 450 μm, the most tip diameter (d) of 25 μm and a length of the curved portion L2 of about 2 mm. Further, all the probe sizes in the embodiments 1 to 5 are the same to each other.

Contact force (probe force) under application of the over-drive for both the probe of the embodiment 1 and the probe of the comparison example were measured. The size of each of the portions of the probe of comparison example is the same as that of the probe of the embodiment 1, and the probe of comparison example is the probe (prior art product) having a bare wire structure made of Paliney 7.

TABLE 1

| | | Over-Drive Amount | | | | | |
|---|---|---|---|---|---|---|---|
| | | 50 μm | 60 μm | 70 μm | 80 μm | 90 μm | 100 μm |
| Con- | Com- | 3.0 | 3.5 | 4.2 | 4.9 | 5.3 | 6.0 |
| tact | parison | | | | | | |
| Force | Exam- | | | | | | |
| | ple 1 | | | | | | |
| | Embod- | 5.1 | 6.1 | 7.0 | 8.1 | 9.0 | 10.0 |
| | iment 1 | | | | | | |
| | Embod- | 6.0 | 6.9 | 8.1 | 9.0 | 10.1 | 11.0 |
| | iment 2 | | | | | | |
| | Embod- | 6.1 | 7.0 | 8.1 | 9.1 | 10.0 | 11.1 |
| | iment 3 | | | | | | |
| | Embod- | 5.0 | 5.9 | 7.0 | 8.0 | 9.9 | 10.0 |
| | iment 4 | | | | | | |
| | Embod- | 6.0 | 7.1 | 8.0 | 9.1 | 10.0 | 11.0 |
| | iment 5 | | | | | | |

A result of measurement is indicated in Table 1. In general, an amount of over-drive is about 50 to 100 μm. In order to attain a positive electrical connection between the probe tip and the aluminum-copper alloy film at the IC chip electrode, it is needed that the contact force is 7 g or more. In the case of the probe of the comparison example, the contact force under application of an amount of over-drive of 50 μm was 3.0 g and the contact force under application of an amount of over-drive of 100 μm was 6.0 g. In the case of the probe of the comparison example, even if the amount of over-drive was 100 μm, it was not possible to attain the aforesaid lower limit value of contact force of 7 g. To the contrary, in the case of the probe of the embodiment 1, the contact force under application of the amount of over-drive of 50 μm was 5.1 g, the contact force under application of 100 μm was 10.0 g and the aforesaid lower limit value of the contact force of 7 g was attained under application of the amount of over-drive of 70 μm or more. Young's modulus of the nickel plated fine wire for the probe applied with a wire drawing operation described above which was used for the probe of the embodiment 1 was 150 GPa, and Young's modulus of the fine wire for the probe made of Paliney 7 with a diameter of 65 μm which was used for the probe of the comparison example was 120 GPa.

Further, introducing another example in the embodiment 1 shows that the nickel-plated fine wire for the probe with a diameter of 126 μm and a plated thickness of 13 μm was manufactured from the wire material with a diameter of 100 μm made of Paliney 7. This nickel-plated fine wire for the probe was made fine in sequence with the wire drawing dies to attain the nickel-plated fine wire for the probe having a diameter of 65 μm and a plated thickness of 6.7 μm and processed by the wire drawing operation. [Embodiment 2]

In this embodiment, the inventors manufactured a probe having a structure in which a nickel alloy plating (Ni/Co alloy plating) containing cobalt by 30 mass % with a thickness of 5 μm was applied to the surface of the core material made of Paliney 7 of palladium alloy, and having a diameter of 65 μm where the wire was drawn with the wire drawing dies.

The method for manufacturing the probe of the embodiment 2 is the same as that of the embodiment 1 except the fact that its component substances of the plating bath used in the plating step are different from those of the aforesaid plating bath in the first embodiment 1. That is, the step of plating operation used the plating bath in which cobalt sulfate (CoSO₄.7H₂O) was added to the component substances of the plating bath of the embodiment 1.

In reference to the probe of the embodiment 2, the contact force under application of the over-drive was measured. A result of measurement is indicated in Table 1. In the case of the probe of the embodiment 2, the contact force with the amount of over-drive being 50 μm was 6.0 g, the contact force with the amount of over-drive being 100 μm was 11.0 g and the aforesaid lower limit value of contact force of 7 g was attained under a state in which the amount of over-drive was about 60 μm or more.

[Embodiment 3]

In this embodiment, the inventors manufactured a probe having a structure in which a nickel alloy plating (Ni/Fe alloy plating) containing iron by 15 mass % with a thickness of 5 μm was applied to the surface of the core material made of Paliney 7 of palladium alloy, and having a diameter of 65 μm where the wire was drawn with the wire drawing dies.

The method for manufacturing the probe of the embodiment 3 is the same as that of the embodiment 1 except the fact that its component substances of the plating bath used in the plating step are different from those of the aforesaid plating bath of the embodiment 1. That is, as the plating bath, the inventors used a plating bath called as “a wolf bath” having, as its major substances, ferrous sulfate (FeSO₄.7H₂O) and nickel sulfate (NiSO₄.6H₂O)

In reference to the probe of the embodiment 3, the contact force under application of the over-drive was measured. A result of measurement is indicated in Table 1. In the case of the probe of the embodiment 3, the contact force with the amount of over-drive being 50 μm was 6.1 g, the contact force with the amount of over-drive being 100 μm was 11.1 g and the aforesaid lower limit value of contact force of 7 g was attained under a state in which the amount of over-drive was 60 μm or more.

[Embodiment 4]

In this embodiment, the inventors manufactured a probe having a structure in which a nickel plating with a thickness of 5 μm was applied to the surface of the core material made of beryllium copper alloy containing beryllium by 2 mass %, and having a diameter of 65 μm where the wire was drawn with the wire drawing dies. The probe of the embodiment 4 was manufactured by the same manufacturing method as that of the aforesaid embodiment 1 under application of the wire material with a diameter of 100 μm made of beryllium copper alloy containing beryllium by 2 mass % in place of the wire material with a diameter of 100 μm made of Paliney 7.

In reference to the probe of the embodiment 4, the contact force under application of the over-drive was measured. A result of measurement is indicated in Table 1. In the case of the probe of the embodiment 4, the contact force with the amount of over-drive being 50 μm was 5.0 g, the contact force with the amount of over-drive being 100 μm was 10.0 g and the aforesaid lower limit value of contact force of 7 g was attained under a state in which the amount of over-drive was 70 μm or more.

[Embodiment 5]

In this embodiment, the inventors manufactured a probe having a structure in which a nickel alloy plating containing cobalt by 30 mass % with a thickness of 5 μm was applied to the surface of the core material made of beryllium copper alloy containing beryllium by 2 mass %, and having a diameter of 65 μm where the wire was drawn with the wire drawing dies. The probe of the embodiment 5 was manufactured by the same manufacturing method as that of the aforesaid embodiment 1 by using the wire material with a diameter of 100 μm made of beryllium copper alloy containing beryllium by 2 mass % in place of the wire material with a diameter of 100 μm made of Paliney 7, and by using a plating bath composed of nickel sulfate (NiSO₄. 6H₂O), nickel chloride (NiCl₂.6H₂O), boric acid (H₃BO₃) and cobalt sulfate (CoSO₄.7H₂O) in place of “Watts bath”.

In reference to the probe of the embodiment 5, the contact force under application of the over-drive was measured. A result of measurement is indicated in Table 1. In the case of the probe of the embodiment 5, the contact force with the amount of over-drive being 50 μm was 6.0 g, the contact force with the amount of over-drive being 100 μm was 11.0 g and the aforesaid lower limit value of contact force of 7 g was attained under a state in which the amount of over-drive was 60 μm or more.

Then, the embodiment of the present invention described in claim 1 will be described as follows.

[Embodiment 6]

The inventors manufactured the probe having a structure in which a nickel plating with a thickness of 5 μm was applied to the surface of the core material with a circular sectional surface made of Paliney 7 of palladium alloy, and having a diameter of 65 μm.

A method for manufacturing the probe of the embodiment 6 will be described. The nickel plated fine wire for the probe with a diameter of 65 μm and a plating thickness of 5 μm was manufactured from the wire material with a diameter of 55 μm made of Paliney 7 containing the aforesaid chemical composition and through the following steps. That is, these steps are (1) an electrolysis degreasing step, (2) a water washing step, (3) an activating step, (4) a water washing step, (5) a strike plating step, (6) a water washing step, (7) a plating step, (8) a water washing step, (9) a drying step and (10) a take-up step. In the plating step for performing an electrical plating, a plating bath called as the aforesaid “Watts bath” was used for the wire material made of Paliney 7 with a diameter of 55 μm, and a nickel plating with a nickel thickness of 5 μm was applied with a cathode current density being 2 to 10A/dm².

Then, the aforesaid nickel plated fine wire for the probe is cut under a predetermined length pitch, a pitch of length of 60 mm, for example. Both a polishing operation for forming a tip shape and a bending operation for forming a curved portion were carried out for the nickel plated fine wire of this predetermined length for the probe to attain the probe with a diameter of 65 μm having a structure in which a nickel plating of a thickness of 5 μm was applied to the surface of the core material made of Paliney 7. A size of this probe (refer to FIG. 4) has a diameter (an outer diameter) D of 65 μm, a tip length L1 of 450 μm, the most tip diameter (d) of 25 μm and a length of the curved portion L2 of about 2 mm. Further, all the probe sizes in the embodiments 6 to 9 are the same to each other.

TABLE 2

| | | Over-Drive Amount | | | | | |
|---|---|---|---|---|---|---|---|
| | | 50 μm | 60 μm | 70 μm | 80 μm | 90 μm | 100 μm |
| Con- | Embod- | 4.5 | 5.6 | 6.4 | 7.6 | 8.5 | 9.5 |
| tact | iment 6 | | | | | | |
| Force | Embod- | 5.0 | 5.9 | 7.0 | 7.9 | 9.0 | 10.0 |
| (g) | iment 7 | | | | | | |
| | Embod- | 4.5 | 5.5 | 6.4 | 7.5 | 8.6 | 9.5 |
| | iment 8 | | | | | | |
| | Embod- | 5.0 | 5.9 | 6.9 | 8.0 | 9.1 | 10.0 |
| | iment 9 | | | | | | |

In reference to the probe of the embodiment 6, the contact force under application of the over-drive was measured. A result of measurement is indicated in Table 2. In the case of the probe of the embodiment 6, the contact force with the amount of over-drive being 50 μm was 4.5 g, the contact force with the amount of over-drive being 100 μm was 9.5 g and the aforesaid lower limit value of contact force of 7 g was attained under a state in which the amount of over-drive was about 75 μm or more.

[Embodiment 7]

The inventors manufactured the probe having a structure in which a nickel alloy plating containing cobalt by 30 mass % with a thickness of 5 μm was applied to the surface of the core material made of Paliney 7 of palladium alloy, and having a diameter of 65 μm.

The method for manufacturing the probe described in the embodiment 7 is the same as that of the embodiment 6 except the fact that the component substances in the plating bath used in the plating step are different from those of the aforesaid plating bath in the aforesaid embodiment 6. That is, at the plating step, the plating bath having cobalt sulfate (CoSO₄.7H₂O) further added to the component substances of the plating bath of the embodiment 6 was used.

In reference to the probe of the embodiment 7, the contact force under application of the over-drive was measured. A result of measurement is indicated in Table 2. In the case of the probe of the embodiment 7, the contact force with the amount of over-drive being 50 μm was 5.0 g, the contact force with the amount of over-drive being 100 μm was 10.0 g and the aforesaid lower limit value of contact force of 7 g was attained under a state in which the amount of over-drive was 70 μm or more.

[Embodiment 8]

The inventors manufactured the probe having a structure in which a nickel plating with a thickness of 5 μm is applied to the surface of the core material made of beryllium copper alloy containing beryllium by 2 mass %, and having a diameter of 65 μm. In the case of the probe of the embodiment 7, the present inventors manufactured it by using the wire material with a diameter of 55 μm made of beryllium copper alloy containing beryllium by 2 mass % in place of the wire material with a diameter of 55 μm made of Paliney 7 under application of the same manufacturing method as that of the embodiment 6.

In reference to the probe of the embodiment 8, the contact force under application of the over-drive was measured. A result of measurement is indicated in Table 2. In the case of the probe of the embodiment 8, the contact force with the amount of over-drive being 50 μm was 4.5 g, the contact force with the amount of over-drive being 100 am was 9.5 g and the aforesaid lower limit value of contact force of 7 g was attained under a state in which the amount of over-drive was about 75 μm or more.

[Embodiment 9]

The inventors manufactured the probe having a structure in which a nickel alloy plating containing cobalt by 30 mass % with a thickness of 5 μm is applied to the surface of the core material made of beryllium copper alloy containing beryllium by 2 mass %, and having a diameter of 65 μm. In the case of the probe of the embodiment 9, the present inventors manufactured it by using the wire material with a diameter of 55 μm made of beryllium copper alloy containing beryllium by 2 mass % in place of the wire material with a diameter of 55 μm made of Paliney 7 and by using a plating bath composed of nickel sulfate (NiSO₄.6H₂O), nickel chloride (NiCl₂.6H₂O), boric acid (H₃Bo₃) and cobalt sulfate (CoSO₄.7H₂O) in place of “Watts bath” under application of the same manufacturing method as that of the embodiment 6.

In reference to the probe of the embodiment 9, the contact force under application of the over-drive was measured. A result of measurement is indicated in Table 2. In the case of the probe of the embodiment 9, the contact force with the amount of over-drive being 50 μm was 5.0 g, the contact force with the amount of over-drive being 100 μm was 10.0 g and the aforesaid lower limit value of contact force of 7 g was attained under a state in which the amount of over-drive was about 70 μm or more.

Further, the present invention is not limited to the probe for the vertical type probe card and having the curved portions, but can also be applied to the linear type probe for the vertical type probe card, having no curved portions and extending straight in a downward direction. In addition, the present invention can also be applied to the probe for a canti-lever type probe card and having its tip bent in a downward direction.

As described above, in accordance with the probe for the probe card of the present invention, it is possible to attain a large contact force as compared with that of the bare wire structure made of either the prior art palladium alloy or beryllium copper alloy when the over-drive is applied to it. With such an arrangement as above, the probe having a diameter of 65 μm can be used for the probe card to inspect the IC chip having a fine pitch such as 100 μm of a pitch size between the electrodes and the present invention can be adapted for a tendency of making a small pitch size between the electrodes of the IC chip as the fine formation of the semiconductor integrated circuit is being promoted.

1. A probe for a probe card characterized in that the same has a structure where either nickel plating or nickel alloy plating is applied to the surface of a core material made of either palladium alloy or beryllium copper alloy.

2. A probe for a probe card characterized in that the same has a structure where either nickel plating or nickel alloy plating is applied to the surface of a core material made of either palladium alloy or beryllium copper alloy and a wire drawing operation with a wire drawing die is performed.

3. A probe for a probe card according to claim 1 characterized in that a gold plating is applied to the upper-most surface of said probe.

4. A probe for a probe card according to claim 2 characterized in that a gold plating is further applied to the upper-most surface of said probe after said wire drawing operation is performed.
